(19) United States
(12) Patent Application Publication
(10) Pub. No.: US 2015/0137668 A1
(43) Pub. Date: May 21, 2015

(54) CERAMIC ELECTRONIC COMPONENT AND METHOD OF MANUFACTURING CERAMIC ELECTRONIC COMPONENT

(71) Applicant: MURATA MANUFACTURING CO., LTD., Nagaokakyo-Shi (JP)

(72) Inventors: Hitomi Hoshino, Nagaokakyo-shi (JP); Ryoko Katayama, Nagaokakyo-shi (JP); Hiroshi Asano, Nagaokakyo-shi (JP)

(21) Appl. No.: 14/561,297

(22) Filed: Dec. 5, 2014

Related U.S. Application Data
(63) Continuation of application No. PCT/JP2013/070325, filed on Jul. 26, 2013.

(30) Foreign Application Priority Data
Jul. 26, 2012 (JP) 2012-165809

(51) Int. Cl. H01L 41/047; H01B 13/00

(52) U.S. Cl. CPC H01L 41/0475; H01B 13/0016
USPC 310/365; 427/77

(57) ABSTRACT

In a piezoelectric ceramic base, a contact interface in contact with an electrode has recess portions surrounded by crystal particles. An average depth T of the recess portions is preferably 1 to 10 μm, and an occupation rate of the recess portions at the contact interface is preferably 65% or more of an area ratio.

### CROSS REFERENCE TO RELATED APPLICATIONS

The present application is a continuation of International application No. PCT/JP2013/070325, filed Jul. 26, 2013, which claims priority to Japanese Patent Application No. 2012-165809, filed Jul. 26, 2012, the entire contents of each of which are incorporated herein by reference.

### FIELD OF THE INVENTION

The present invention relates to a ceramic electronic component and a method of manufacturing the ceramic electronic component.

### BACKGROUND OF THE INVENTION

In concomitance with development of electronic technology in recent years, various types of ceramic electronic components have been mounted in electronic devices.

Incidentally, in this type of ceramic electronic component, when an external electrode is formed on an outer surface, heretofore, the adhesion between a ceramic base and the external electrode is secured by roughening the surface of the ceramic base. For this roughening purpose, etching using an acidic solution or an alkali solution or sand blasting is performed, or the composition of component materials and/or the blending amounts thereof are appropriately adjusted.

For example, Patent Document 1 has proposed a circuit substrate in which a surface wire conductor including a metal component containing silver as a primary component, a glass component, and a metal oxide containing Cu₂O or MnO₂ is formed on a surface of a ceramic substrate, the total of the glass component and the metal oxide of the surface wire conductor is 0.1 to 30 parts by weight with respect to 100 parts by weight of the metal component, and the interface between the ceramic substrate and the surface wire conductor has a roughness of 5 μm or more.

In the Patent Document 1, in order to increase an adhesion force between the ceramic substrate and the surface wire conductor, the surface of the ceramic substrate is roughened by adjusting the amounts of the glass component and the metal oxide with respect to the amount of the metal component so as to obtain a so-called anchor effect between the ceramic substrate and the surface wire conductor.

Patent Document 1: Japanese Unexamined Patent Application Publication No. 2002-76609 (claim 1, and paragraphs [0043] and [0044])

### SUMMARY OF THE INVENTION

However, according to Patent Document 1, since the surface of the ceramic substrate is roughened, the strength of the ceramic substrate itself is decreased, and as a result, structural defects, such as cracks and fractures, are liable to occur, so that the reliability may be degraded in some cases. In addition, the mechanical characteristics of the ceramic substrate are degraded, for example, due to warpage and/or undulation generated therein, and as a result, the reliability may also be degraded in some cases.

In addition, even when the surface of the ceramic base is etched or sand blasted to increase the adhesion, it is believed that, for example, the generation of structural defects, the degradation of mechanical characteristics, and the lack of reliability may arise in some cases as in the case disclosed in Patent Document 1.

In consideration of the situation as described above, the present invention was made, and an object of the present invention is to provide a highly reliable ceramic electronic component which has good adhesion between a ceramic base and a conductive portion, which can avoid the generation of structural defects, and which can secure desired good mechanical characteristics and a method for manufacturing the ceramic electronic component described above.

In order to achieve the above object, a ceramic electronic component of the present invention is a ceramic electronic component in which a conductive portion is formed on at least a part of at least one primary surface of a ceramic base, and in the ceramic base, at least a part of a contact interface in contact with the conductive portion provided on the primary surface has structural portions formed from crystal particles.

In addition, in the ceramic electronic component of the present invention, the structural portions preferably include recess portions surrounded by the crystal particles.

Accordingly, a highly reliable ceramic electronic component can be obtained which has good adhesion between the ceramic base and the conductive portion, which can avoid the generation of structural defects, and which can secure desired good mechanical characteristics.

In addition, in the ceramic electronic component of the present invention, the recess portions are each preferably formed to have an approximately circular shape when viewed in a plan view.

Furthermore, in the ceramic electronic component of the present invention, in order to form the recess portions, at least a part of the contact interface is preferably formed to have a spherical concave-convex shape.

In addition, in the ceramic electronic component of the present invention, the recess portions preferably have an average depth of 1 to 10 μm.

Accordingly, a ceramic electronic component can be obtained which has sufficient adhesion and good mechanical characteristics with suppressed variation.

Furthermore, in the ceramic electronic component of the present invention, an occupation rate of the recess portions at the contact interface is preferably 65% or more on the area ratio.

Accordingly, desired adhesion can be more reliably secured.

In addition, in the ceramic electronic component of the present invention, the recess portions are preferably formed to have approximately the same size when viewed in a plan view.

In addition, in the ceramic electronic component of the present invention, the structural portions also preferably include protruding portions formed from the crystal particles.

In this case, as that described above, a highly reliable ceramic electronic component can also be obtained which has good adhesion between the ceramic base and the conductive portion, which can avoid the generation of structural defects, and which can secure desired good mechanical characteristics.

In addition, in the ceramic electronic component of the present invention, the protruding portions preferably have an average height of 0.5 to 10 μm.

Accordingly, a ceramic electronic component can be obtained which has sufficient adhesion and good mechanical characteristics with suppressed variation.

In addition, in the ceramic electronic component of the present invention, an occupation rate of the protruding portions at the contact interface is preferably 20% or more on the area ratio.

Accordingly, desired adhesion can be more reliably secured.

Furthermore, in the ceramic electronic component of the present invention, the protruding portions are preferably formed to have approximately the same size when viewed in a plan view.

In addition, in the ceramic electronic component of the present invention, an internal electrode is preferably embedded in the ceramic base.

In addition, a method for manufacturing a ceramic electronic component of the present invention comprises: a green sheet-forming step of forming a ceramic green sheet by mold processing of a ceramic raw material; a ceramic molded body-forming step including preparing a molding die having a press surface which at least partially has convex shapes, and pressing at least one primary surface of the ceramic green sheet by the press surface of the molding die to form a ceramic molded body in at least a part of which concave shapes are formed; a firing step of firing the ceramic molded body to form a ceramic base in which recess portions surrounded by crystal particles are formed in at least a part of a primary surface; and an electrode-forming step of forming an electrode on the surface of the ceramic base.

In addition, a method for manufacturing a ceramic electronic component of the present invention comprises: a green sheet-forming step of forming a ceramic green sheet by mold processing of a ceramic raw material; a ceramic molded body-forming step including preparing a molding die having a press surface which at least partially has convex shapes, and pressing at least one primary surface of the ceramic green sheet by the press surface of the molding die to form a ceramic molded body in at least a part of which concave shapes are formed; a firing step of firing the ceramic molded body to form a ceramic base in which protruding portions are formed on at least a part of a primary surface; and an electrode-forming step of forming an electrode on the surface of the ceramic base.

A ceramic electronic component of the present invention is a ceramic electronic component in which a conductive portion is formed on at least a part of at least one primary surface of a ceramic base, and in the ceramic base, since at least a part of a contact interface in contact with the conductive portion provided on the primary surface has structural portions (recess portions or protruding portions) formed from crystal particles, the contact interface has a strong anchor effect. As a result, since the adhesion between the ceramic base and the conductive portion is improved, and furthermore, the strength of the ceramic base itself is not decreased, a highly reliable ceramic electronic component can be obtained which can avoid the generation of structural defects, such as cracks and fractures, and which can secure desired good mechanical characteristics.

In addition, a method for manufacturing a ceramic electronic component of the present invention comprises: a green sheet-forming step of forming a ceramic green sheet by mold processing of a ceramic raw material; a ceramic molded body-forming step including preparing a molding die having a press surface which at least partially has convex shapes, and pressing at least one primary surface of the ceramic green sheet by the press surface of the molding die to form a ceramic molded body in at least a part of which concave shapes are formed; a firing step of firing the ceramic molded body to form a ceramic base which has recess portions surrounded by crystal particles in at least a part of a primary surface; and an electrode-forming step of forming an electrode on the surface of the ceramic base. Accordingly, the ceramic electronic component can be easily manufactured by using a molding die.

In addition, in the case in which a firing step forms a ceramic base which has protruding portions formed from crystal particles on at least a part of a primary surface, the ceramic electronic component can also be easily manufactured.

### BRIEF DESCRIPTION OF THE DRAWINGS

FIG. 1 is a cross-sectional view schematically showing a piezoelectric component as one embodiment (first embodiment) of a ceramic electronic component of the present invention.

FIG. 2 is an enlarged cross-sectional view of the A portion shown in FIG. 1.

FIG. 3 is a cross-sectional view showing one example of a molding die used in a step of manufacturing the piezoelectric element.

FIG. 4 is a cross-sectional view showing the state of press molding.

FIG. 5 is a cross-sectional view showing one example of a piezoelectric ceramic base.

FIG. 6 is a required part enlarged cross-sectional view of a second embodiment of the ceramic electronic component of the present invention.

FIG. 7 is a cross-sectional view showing one example of a piezoelectric ceramic base according to the second embodiment.

FIG. 8 is a cross-sectional view schematically showing a piezoelectric component as a third embodiment of the ceramic electronic component of the present invention.

FIG. 9 is a SEM image of Sample No. 4.

FIG. 10 is a SEM image of Sample No. 23.

FIG. 11 is a view showing the state in FIG. 9 in which recess portions are each formed to have an approximately circular shape when viewed in a plan view.

FIG. 12 is a SEM image of Sample No. 44.

### DETAILED DESCRIPTION OF THE PREFERRED EMBODIMENTS

Next, embodiments of the present invention will be described in detail.

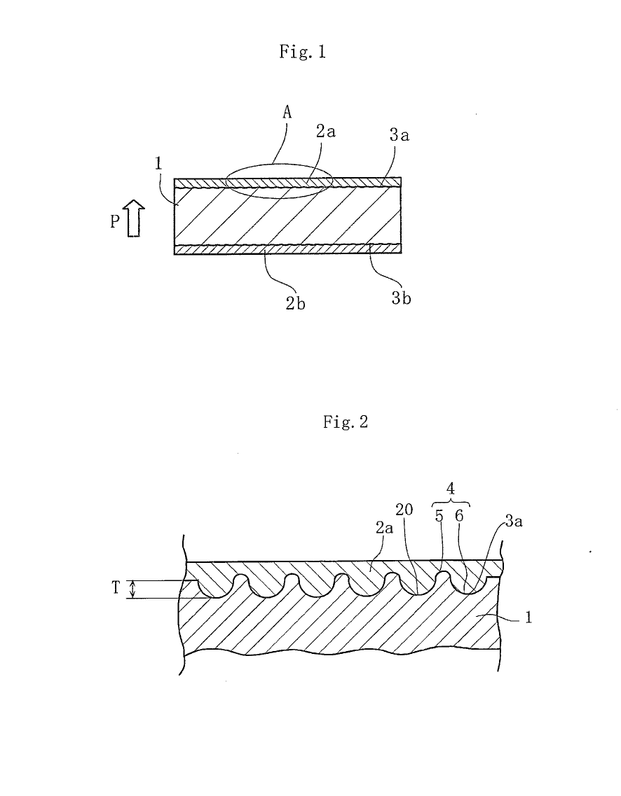

FIG. 1 is a cross-sectional view schematically showing one embodiment (first embodiment) of a piezoelectric component as a ceramic electronic component of the present invention.

This piezoelectric component includes a piezoelectric ceramic base 1 containing a piezoelectric ceramic material, such as lead zirconate titanate (hereinafter referred to as “PZT”), as a primary component and electrodes 2a and 2b which are formed on two primary surfaces of the piezoelectric ceramic base 1 and which contains a conductive material, such as Ag, as a primary component, and this piezoelectric component is processed by a polarization treatment in an arrow P direction.

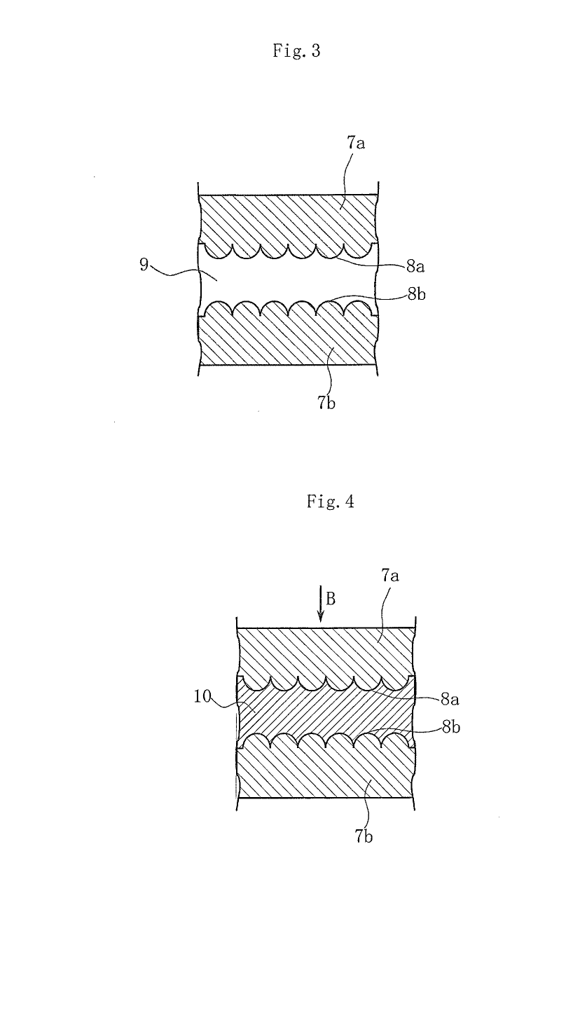

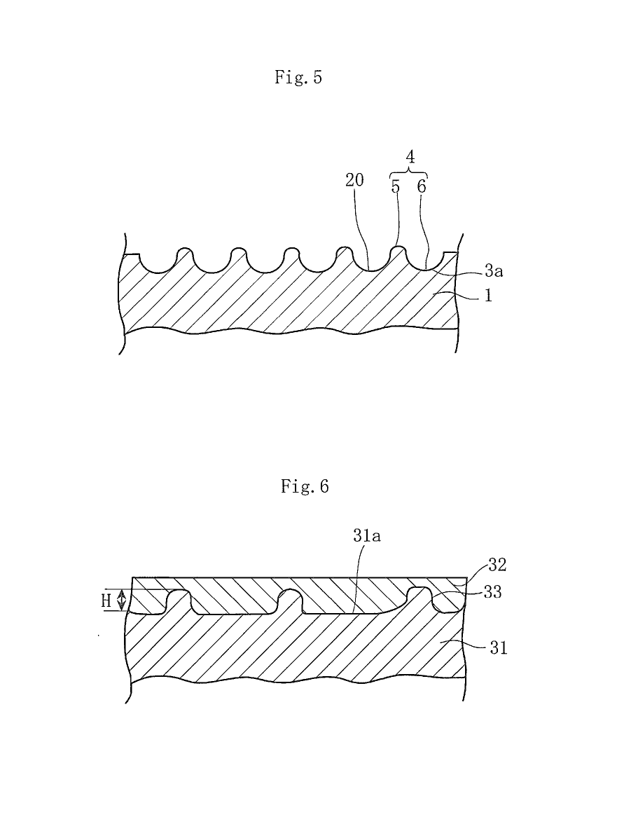

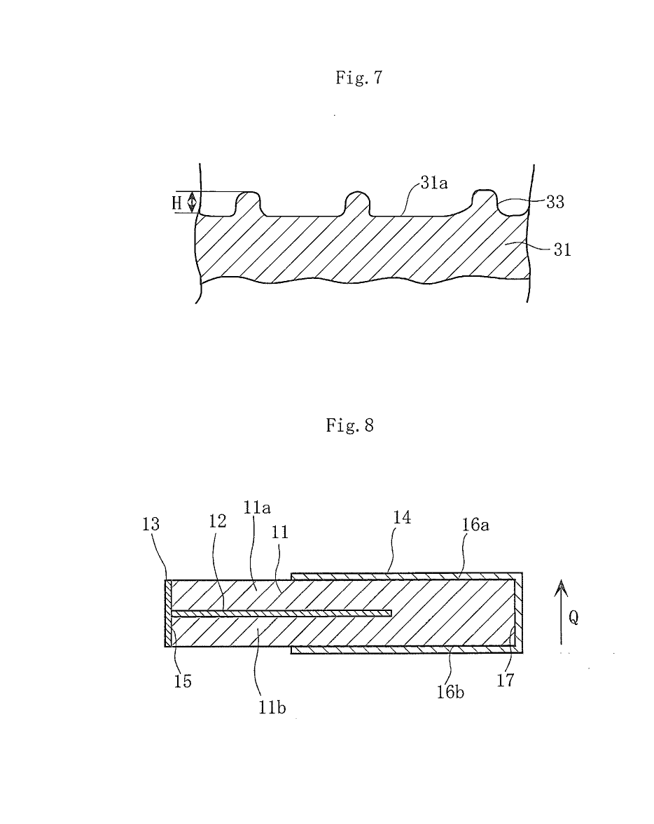

FIG. 2 is an enlarged cross-sectional view of the A portion shown in FIG. 1.

In this piezoelectric ceramic base 1, a contact interface in contact with the electrode 2a on a primary surface 3a has a spherical concave-convex portion 4. In particular, this spherical concave-convex portion 4 is formed in such a way that semispherical convex portions 5 and semispherical concave portions 6 are alternately connected to each other in a regular manner. In addition, the semispherical concave portions 6 form a recess portion 20 (structural portion) surrounded by crystal particles. That is, in this piezoelectric ceramic base 1, the contact interface with the electrode 2a is formed to have a spherical concave-convex shape so that the recess portions 20 having an average depth T are formed.

Since the contact interface between the piezoelectric ceramic base 1 and the electrode 2a has the recess portions 20 surrounded by the crystal particles as described above, the contact interface has a strong anchor effect, and hence, the adhesion between the piezoelectric ceramic base 1 and the electrode 2a can be improved. In addition, since the contact interface of the piezoelectric ceramic base 1 with the electrode 2a has the recess portions 20 surrounded by the crystal particles as described above, the generation of structure defects, such as cracks and fractures, can be avoided without causing a decrease in strength of the ceramic base 1 itself. Furthermore, since the spherical concave-convex portion 4 forming the recess portions 20 is formed to have a regular shape unlike the case in which the primary surface of the piezoelectric ceramic base 1 is simply roughened in an irregular manner, a higher effect of suppressing the generation of warpage and undulation and the decrease in flexural strength can be obtained. Accordingly, a highly reliable piezoelectric component can be obtained which can secure desired mechanical strength.

In addition, in the above first embodiment, although the contact interface between the piezoelectric ceramic base 1 and the electrode 2a is shown, a contact interface between the piezoelectric ceramic base 1 and the electrode 2b has the same function as that described above, and the contact interface in contact with the electrode 2b on a primary surface 3b also has recess portions 20 surrounded by crystal particles.

In this embodiment, although the average depth T of the recess portions 20 is not particularly limited, in order to secure good mechanical characteristics while sufficient adhesion is secured, a depth of 1 to 10 μm is preferable.

That is, in order to secure the adhesion by a sufficient anchor effect of each of the contact interfaces between the piezoelectric ceramic base 1 and the electrodes 2a and 2b, the average depth T of the recess portions 20 is preferably at least 1 μm or more.

On the other hand, when the average depth T of the recess portions 20 is more than 10 μm, although the mechanical characteristics, such as the flexural strength, are superior to those of the case in which the contact interface is roughened, the mechanical characteristics may be degraded in some cases as compared to those of the case in which the average depth T is 10 μm or less.

In addition, in the piezoelectric ceramic base 1, the recess portions 20 are not required to be formed over the entire region of the contact interface in contact with each of the electrodes 2a and 2b and may be formed in at least a part of the above contact interface.

However, when an occupation rate of the recess portions 20 at the contact interface is less than 65% on the area ratio, since the occupation rate of the recess portions 20 is low, the adhesion may be degraded in some cases.

In addition, the piezoelectric component according to the first embodiment can be manufactured as described below.

First, ceramic raw materials, such as Pb₃O₄, ZrO₂, and TiO₂, are prepared, and predetermined amounts thereof were weighed. Next, after the raw materials thus weighed were charged into a ball mill together with a pulverizing medium, such as PSZ (partially stabilized zirconia), and water, mixing and wet-pulverizing are performed. Subsequently, a dehydration/drying treatment was performed, and a calcination treatment is then performed at a predetermined temperature (such as approximately 800° C. to 1,000° C.), so that a calcined product is obtained.

Next, after this calcined product is charged into a ball mill together with an organic binder, a dispersant, water, and a pulverizing medium and is then mixed together, wet-pulverizing is again performed to form a ceramic slurry. Subsequently, by a mold processing method, such as a doctor blade method, a ceramic green sheet having a predetermined thickness is formed.

Next, a molding die (a die used for molding) is prepared.

FIG. 3 is a required part enlarged cross-sectional view showing one example of the molding die, and this molding die includes an upper die 7a in which a bottom surface 8a has semispherical convex press surface shapes and a lower die 7b in which a top surface 8b has semispherical convex press surface shapes.

In addition, after a multilayer ceramic green sheet 10 is formed by laminating a predetermined number of ceramic green sheets to each other so as to have a predetermined thickness after firing, as shown in FIG. 4, the multilayer ceramic green sheet 10 is provided in a space 9 formed between the top surface 8b of the lower die 7b and the bottom surface 8a of the upper die 7a and is then pressurized by a predetermined pressure in an arrow B direction. Accordingly, the press surface shapes of the upper die 7a and the lower die 7b are transferred on the primary surfaces of the multilayer ceramic green sheet 10, thereby forming a ceramic molded body having concave-convex shaped primary surfaces.

Next, after the ceramic molded body is released from the molding die, a debinding treatment is performed at a temperature of approximately 400° C. to 600° C., and the ceramic molded body thus treated is received in an air-tightly sealed sheath and is then processed by a firing treatment in accordance with a predetermined firing profile. As a result, the piezoelectric ceramic base 1 having the recess portions 20 surrounded by crystal particles is formed.

Subsequently, by any of arbitrary selected treatments, such as a thin film forming method including a sputtering method or a vacuum deposition method, a plating method, and a firing treatment of an electrode paste, the electrodes 2a and 2b are formed on the two primary surfaces 3a and 3b, respectively, of the piezoelectric ceramic base 1.

Subsequently, a polarization treatment is performed in silicone oil heated to a predetermined temperature by applying a predetermined electric field, so that the piezoelectric component is manufactured.

In the piezoelectric ceramic base 1 of the piezoelectric component as described above, since the contact interfaces in contact with the electrodes 2a and 2b on the primary surfaces 3 each have the recess portions 20 surrounded by the crystal particles, the contact interfaces each have a strong anchor effect. Accordingly, since the adhesion between the piezoelectric ceramic base 1 and each of the electrodes 2a and 2b is improved, and furthermore, the strength of the piezoelectric ceramic base 1 itself is not decreased, a highly reliable ceramic electronic component can be obtained which can avoid the generation of structural defects, such as cracks and fractures, and which can secure desired good mechanical characteristics.

In the first embodiment described above, although the recess portions 20 are formed to have a spherical concave-convex shape, the recesses are only required to be present and are not required to have a spherical concave-convex shape.

FIG. 6 is a required part enlarged cross-sectional view schematically showing a second embodiment of a piezoelectric component as the ceramic electronic component of the present invention, and in this second embodiment, an electrode 32 is formed on a primary surface 31a of a piezoelectric ceramic base 31, and the ceramic base 31 is formed so that the primary surface 31a has protruding portions 33 (structural portions) with an average height H.

In addition, a method for forming a primary surface shape (recess portions or protruding portions) of a piezoelectric ceramic base may not be simply determined, and the primary surface shape may be adjusted using various factors, such as types of ceramic materials and firing profiles, which contribute to the sintered state.

Since the protruding portion 33 thus formed has a function similar to that of the recess portion 20 which has been described in detail in the first embodiment (see FIG. 2), and the contact interface has a strong anchor effect, the adhesion between the ceramic base 31 and the electrode 32 is improved. Furthermore, in this instance, a highly reliable ceramic electronic component can also be obtained which can avoid the generation of structural defects, such as cracks and fractures, without decreasing the strength of the ceramic base 31 itself and which can secure desired good mechanical characteristics, and hence the object of the present invention can be achieved.

In this embodiment, although the average height H of the protruding portions 33 is not particularly limited, in order to secure good mechanical characteristics with no variation while sufficient adhesion is secured, the average height H is preferably 0.5 to 10 μm.

That is, in order to secure the adhesion by a sufficient anchor effect of the contact interface between the piezoelectric ceramic base 31 and the electrode 32, the average height H of the protruding portions 33 is preferably at least 0.5 μm or more.

On the other hand, when the average height H of the protruding portions 33 is more than 10 μm, although the adhesion is further improved because of a more preferable anchor effect, the variation of mechanical characteristics is liable to occur. Hence, the average height H of the protruding portions 33 is preferably 10 μm or less.

In addition, in the piezoelectric ceramic base 31, as in the case of the first embodiment, the entire region of the contact interface in contact with the electrode 32 is not required to form the protruding portions 33, and at least a part of the contact interface may form the protruding portions 33.

However, when the occupation rate of the protruding portions 33 at the contact interface is less than 20% on the area ratio, since the occupation rate of the protruding portions 33 is low, the adhesion may be degraded in some cases.

In addition, the piezoelectric component according to the second embodiment may also be manufactured by a method and a procedure similar to those of the first embodiment.

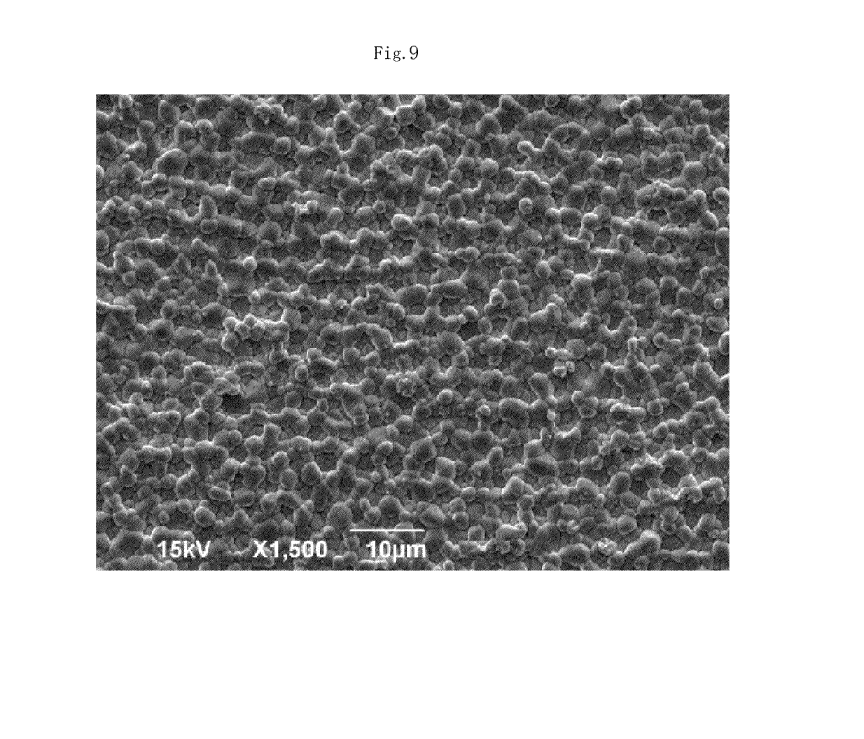

FIG. 8 is a cross-sectional view schematically showing a piezoelectric component according to a third embodiment of the ceramic electronic component of the present invention.

In this piezoelectric component, an internal electrode 12 formed from Ag, Ag—Pd, or the like is embedded in a piezoelectric ceramic base 11, and external electrodes 13 and 14 are formed on primary surfaces of the piezoelectric ceramic base 11. In addition, in the ceramic base 11, at least a part of the contact interface between the primary surface and the external electrode 14 has recess portions surrounded by crystal particles as in the case of the first embodiment or protruding portions formed by crystal particles as in the case of the second embodiment.

That is, this piezoelectric ceramic base 11 has two piezoelectric ceramics 11a and 11b, and the recess portions or the protruding portions are formed in or on primary surfaces 16a and 16b thereof. In addition, the internal electrode 12 is formed so as to cover more than a half of the other primary surface of a piezoelectric ceramic base 11b and so that one end is exposed to the surface thereof, and a piezoelectric ceramic base 11a is laminated on and integrated with the internal electrode 12 and the piezoelectric ceramic base 11b. In addition, the external electrode 13 is formed on one side surface portion 15 of the piezoelectric ceramic base 11 so as to be electrically connected to the internal electrode 12. In addition, parts of the external electrode 14 are respectively formed on the primary surface 16a of the piezoelectric ceramic base 11a and on the primary surface 16b of the piezoelectric ceramic base 11b so as to face the internal electrode 12 and so as to be electrically connected to each other through the other side surface portion 17.

This piezoelectric component is polarized in an arrow Q direction, and by application of a voltage between the external electrodes 13 and 14, an electric field is generated between the internal electrode 12 and the external electrode 14, so that the vibration occurs in a bending mode.

This piezoelectric component is manufactured as described below.

First, by a method and a procedure similar to those of the first embodiment, a ceramic green sheet is formed.

Next, after an internal electrode-forming conductive paste is applied onto a part of a ceramic green sheet to form a conductive layer, a ceramic green sheet on which no conductive layer is formed is laminated on the ceramic green sheet described above, so that a multilayer ceramic green sheet is formed.

Next, as in the case of the first embodiment, by the use of a lower die having a top surface with semispherical convex press surface shapes and an upper die having a bottom surface with semispherical convex press surface shapes, the above multilayer ceramic green sheet is sandwiched between the lower and the upper dies and is then pressurized by a predetermined pressure, so that a ceramic molded body having spherical concave-convex shapes on the primary surfaces thereof is formed. Subsequently, this ceramic molded body is fired, so that a ceramic sintered body having recess portions in or protruding portions on the primary surfaces thereof is formed.

Next, a sputtering treatment is performed on the both primary surfaces of this ceramic sintered boy using a target of Ag or the like to form electrodes to be used for a polarization treatment. Subsequently, after a polarization treatment is performed in insulating oil at a temperature of 150° C. by applying a predetermined direct-current voltage between the two primary surfaces, the electrodes used for a polarization treatment are removed by etching, so that the piezoelectric ceramic base 11 in which the internal electrode 12 is embedded is obtained.

In addition, the piezoelectric ceramic base 11 thus obtained is appropriately cut so that the internal electrode 12 is disposed at a predetermined position and is then again processed by a sputtering treatment using a target of Ag or the like to form the external electrodes 13 and 14 on the outer surfaces of the piezoelectric ceramic base 11, so that the piezoelectric component is manufactured.

In this third embodiment described above, the external electrode (conductive portion) 14 is formed on at least a part of the primary surface of the piezoelectric ceramic base 11, and in the piezoelectric ceramic base 11, at least a part of each of the contact interfaces in contact with the external electrode 14 on the primary surfaces 16a and 16b has the recess portions surrounded by crystal particles or the protruding portions formed thereby. Hence, as in the cases of the first and the second embodiments, a highly reliable piezoelectric component can be obtained which has good adhesion between the piezoelectric ceramic base 11 and the external electrode 14, which can avoid the generation of structural defects, and which can secure desired good mechanical characteristics.

In addition, the present invention is not limited to the embodiments described above. In the embodiments described above, since the semispherical concave shapes are formed in the primary surfaces of the ceramic molded body by the use of the upper die 7a and the lower die 7b having semispherical convex shapes 8a and 8b, respectively, and firing is then performed, the primary surfaces of the ceramic sintered body are formed to have the recess portions 20 or the protruding portions 33, which have a spherical concave-convex shape. However, the semispherical convex press surface shapes 8a and 8b of the upper die 7a and the lower die 7b are only one preferable embodiment, and as long as the press surface has convex shapes, the recess portions 20 or the protruding portions 20 can be easily formed.

In addition, in the present invention, as long as at least a part of each of the contact interfaces between the primary surfaces of the piezoelectric ceramic base 1 and the electrode 2a and 2b has the structural portions, such as the recess portions 20 or the protruding portions 33, the method for forming the structural portions as described above is not limited to those described in the above embodiments. However, when the structural portions, such as the recess portions 20 or the protruding portions 33, are formed over the entire or approximately the entire primary surface of the contact interface of the piezoelectric ceramic base 1 or 31, a ceramic electronic component can be obtained which has more preferable adhesion between the piezoelectric ceramic base 1 and the electrodes 2a and 2b or between the piezoelectric ceramic base 31 and the electrode 32, and more preferable mechanical strength.

In addition, the shape of the structural portion, such as the recess portion 20 or the protruding portion 33, is not particularly limited, and various shapes, such as an approximately circular shape or a polygonal shape, may also be used. In addition, when the sizes of the recess portions 20 or the protruding portions 33 are approximately the same when viewed in a plan view, a ceramic electronic component, such as a piezoelectric component, can be obtained which has more preferable adhesion between the piezoelectric ceramic base 1 and the electrode 2 or between the piezoelectric ceramic base 31 and the electrode 32 and more preferable mechanical strength.

In addition, in the above embodiments, although the multilayer ceramic green sheet is sandwiched between the upper die and the lower die and is then pressure-bonded for mold processing, the ceramic molded body may also be formed in such a way that after being dehydrated and dried, the ceramic slurry described above is poured into a cavity which is a die frame formed between the upper die and the lower die and is then heated and pressure-bonded for press molding.

In addition, although the piezoelectric component has been described by way of example in the above embodiments, the present invention may be widely applied to any ceramic electronic components as long as a conductive layer is formed on at least a part of at least one primary surface of a ceramic base. Furthermore, besides the piezoelectric component described above, the present invention may also be widely applied to various types of multilayer ceramic electronic components, ceramic substrates, ceramic multilayer substrates, and the like.

Next, examples of the present invention will be described in detail.

### EXAMPLE 1

(Formation of Test Element)

[Sample Nos. 1 to 17]

First, after a PZT material, an organic binder, and water at a ratio of 100:7.5:15 on a parts by weight basis were charged with an appropriate amount of at least one additive into a ball mill in which PZT (partially stabilized zirconia) balls were received, mixing and pulverizing were sufficiently performed in a wet state, thereby forming a ceramic slurry.

Subsequently, mold processing was performed on the ceramic slurry provided on a PET (poly(ethylene terephthalate)) film using a doctor blade method, thereby forming a ceramic green sheet having a thickness of approximately 30 μm.

In addition, plurality of ceramic green sheets were laminated to each other so that the thickness of a piezoelectric ceramic base after firing was approximately 150 μm, and as a result, a multilayer ceramic green sheet was obtained.

Subsequently, the multilayer ceramic green sheet described above was sandwiched between a lower die having an upper press surface with semispherical convex shapes and an upper die having a lower press surface with semispherical concave shapes and was then pressurized at a pressure of 480 MPa (500 kg/cm²), so that the above press surface shapes were transferred on the primary surfaces of the multilayer ceramic green sheet. Next, the multilayer ceramic green sheet was cut into a size of approximately 20 mm×30 mm, so that a ceramic molded body having primary surfaces with spherical concave-convex shapes was obtained.

Subsequently, the ceramic molded body was fired, so that a piezoelectric ceramic base was obtained.

Next, after Ag was deposited on the two primary surfaces of the piezoelectric ceramic base to form external electrodes, a polarization treatment was performed by applying a direct-current voltage, so that test elements of the present invention of Sample Nos. 1 to 17 were obtained.

[Sample No. 18]

Except that after the multilayer ceramic green sheet was formed, by the use of a lower die and an upper die, a top surface and a bottom surface of which each had a flat press surface, pressure molding was performed on the multilayer ceramic green sheet to form a ceramic molded body, a test element of Sample No. 18 was formed by a method and a procedure similar to those of the test elements of Sample Nos. 1 to 17, and this test element of Sample No. 18 was used as a standard element.

[Sample No. 19]

Except that the both primary surfaces of the ceramic molded body obtained in the manufacturing process of Sample No. 18 were roughened by sand blasting, a test element of Sample No. 19 was formed by a method and a procedure similar to those of the test element of Sample No. 18, and this test element of Sample No. 19 was used as a sand blast element.

(Evaluation of Test Element)

By using 10 test elements of each of Sample Nos. 1 to 17, the average depth T of the recess portions and the occupation rate thereof at the contact interface between the piezoelectric ceramic base and the electrode were obtained by processing an image photographed by a laser microscope.

Next, by using 10 test elements of each of Sample Nos. 1 to 19, the generation of structural defects, such as cracks and fractures, was checked by visual inspection. In addition, for the evaluation of the structural defects, when at least one of the 10 test elements had a structural defect, this test element sample was regarded as a defective (×), and when no structural defects were observed in the 10 test elements, this test element sample was regarded as a good product (◯).

In addition, by using 10 test elements of each of Sample Nos. 1 to 19, a peeling test was performed using a tensile testing machine to measure the adhesion strength between the piezoelectric ceramic base and the electrode, so that the adhesion was evaluated.

In addition, by using 10 test elements of Sample No. 1 to 19, flexural strength was measured using a three-point flexural test, so that the mechanical characteristics were evaluated.

Table 1 shows the average depth T of the recess portions, the occupation rate (average value) of the recess portions, the presence of the structural defects, the adhesion strength (average value), the average value of the flexural strengths, and the standard deviation σ thereof, of the test elements of each of Samples 1 to 19.

TABLE 1

| | | | | | Flexural Strength | |
|---|---|---|---|---|---|---|
| | Average Depth | Occupation | Generation | Adhesion | Average | Standard |
| Sample | T of Recess | Rate of Recess | of Structural | Strength | Value | Deviation |
| No. | Portions (μm) | Portions (%) | Defects | (MPa) | (MPa) | σ (—) |
| 1 | 1 | 72 | ∘ | 2.27 | 102 | 5 |
| 2 | 2 | 72 | ∘ | 2.36 | 103 | 3 |
| 3 | 3 | 72 | ∘ | 2.74 | 106 | 5 |
| 4 | 4 | 72 | ∘ | 3.00 | 107 | 8 |
| 5 | 5 | 72 | ∘ | 3.36 | 103 | 4 |
| 6 | 6 | 72 | ∘ | 3.49 | 104 | 7 |
| 7 | 7 | 72 | ∘ | 3.56 | 105 | 6 |
| 8 | 8 | 72 | ∘ | 3.63 | 105 | 6 |
| 9 | 9 | 72 | ∘ | 3.61 | 101 | 4 |
| 10 | 10 | 72 | ∘ | 3.68 | 105 | 7 |
| 11*²⁾ | 15 | 72 | ∘ | 3.82 | 99 | 8 |
| 12*²⁾ | 20 | 72 | ∘ | 3.80 | 99 | 10 |
| 13*³⁾ | 5 | 48 | ∘ | 2.31 | 105 | 5 |
| 14*³⁾ | 5 | 55 | ∘ | 2.53 | 107 | 6 |
| 15*³⁾ | 5 | 62 | ∘ | 2.98 | 104 | 5 |
| 16 | 5 | 67 | ∘ | 3.38 | 105 | 6 |
| 17 | 5 | 70 | ∘ | 3.39 | 103 | 6 |

| | | | | | |
|---|---|---|---|---|---|
| 18*¹⁾ | Standard Element | ∘ | 1.08 | 105 | 6 |
| 19*¹⁾ | Sand Blast Element | x | 4.04 | 78 | 17 |

*¹⁾indicates out of scope of a preferred embodiment of the present invention.
*²⁾indicates out of scope of a preferred embodiment of the present invention.
*³⁾indicates out of scope of a preferred embodiment of the present invention.

It was found that in the test element of Sample No. 18, since the contact interface between the piezoelectric ceramic base and the electrode was flat, and the structural portions, such as the recess portions or the protruding portions, formed from crystal particles were not present, the adhesion strength was low, such as 1.08 MPa, and the adhesion was inferior.

In the test element of Sample No. 19, since the primary surface of the piezoelectric ceramic base was roughened by a sand blast treatment, the adhesion strength was increased to 4.04 MPa as compared to that of the standard element (Sample No. 18). However, on the other hand, since the mechanical strength of the piezoelectric ceramic base itself was decreased by the above roughening, the generation of structural defects, such as cracks and fractures, was observed. In addition, the flexural strength was low, such as 78 MPa, and furthermore, the variation thereof was increased to have a standard deviation σ of 17, so that the reliability was degraded.

Accordingly, it was found that when the structural portions, such as the recess portions or the protruding portions, formed from crystal particles were not present on the primary surface of the piezoelectric ceramic base, or when the primary surface of the piezoelectric ceramic base was simply roughened by sand blasting or the like, besides the generation of structural defects, the mechanical characteristics were degraded, and as a result, the reliability was also degraded.

On the other hand, it was found that in the test elements of Sample Nos. 1 to 17, since the primary surface of the piezoelectric ceramic base had the recess portions (structural portions) surrounded by crystal particles, the adhesion strength was 2.27 to 3.82 MPa, and compared to that of the standard element (Sample No. 18), the adhesion was significantly improved. In addition, it was also found that since the flexural strength had an average value of 99 to 107 MPa and a standard deviation σ of 4 to 10, unlike the case of the sand blast element (Sample No. 19), a highly reliable ceramic electronic component could be obtained which could secure good mechanical characteristics without generating structural defects.

However, in the test elements of Sample Nos. 11 and 12, it was found that since the average depth T of the recess portions was 15 to 20 μm, which was more than 10 μm, the flexural strength was slightly decreased to 99 MPa, and the variation thereof tended to slightly increase so that the standard deviation σ was 8 to 10.

In addition, in the test elements of Sample Nos. 13 to 15, it was found that since the occupation rate of the recess portions was 48% to 62%, which was less than 65%, the adhesion strength tended to decrease.

As described above, since the primary surface of the piezoelectric ceramic base forms the recess portions surrounded by crystal particles, the adhesion is significantly improved as compared to that of the standard element (Sample No. 18), the mechanical characteristics can be secured without causing the generation of the structural defects unlike the case of the sand blast element (Sample No. 19), and the reliability can also be controlled in an acceptable range. In addition, it was found that in order to obtain more preferable adhesion and mechanical characteristics and to secure more preferable reliability by suppressing the variation among products, the average depth T of the recess portions was preferably 1 to 10 μm, and the occupation rate thereof was preferably 65% or more.

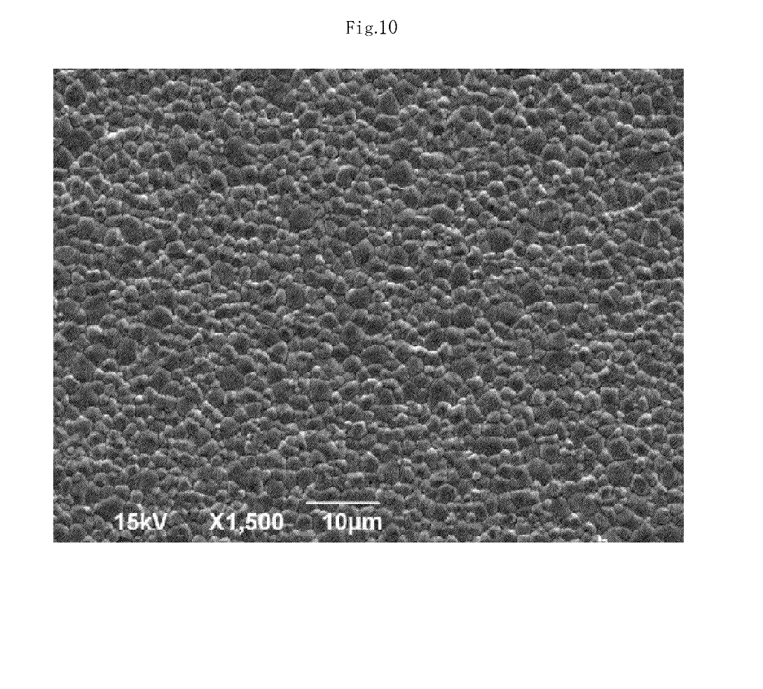

FIG. 9 is a SEM image of the primary surface of the piezoelectric ceramic base of Sample No. 4, and FIG. 10 is a SEM image of the primary surface of the piezoelectric ceramic base of Sample No. 18.

In the standard element of Sample No. 18 shown in FIG. 10, since the multilayer ceramic green sheet was pressurized and sintered while the flat shape of each primary surface thereof was maintained, the sintered surface was also formed to have a flat shape.

On the other hand, in the test element of Sample No. 4 shown in FIG. 9, by the use of the lower die having a top surface with semispherical convex shapes and the upper die having a bottom surface with semispherical convex shapes, the both primary surfaces of the multilayer ceramic green sheet are pressurized so that the press surface shapes are transferred to the respective primary surfaces, and firing is then performed; hence, the crystal particles form three-dimensional recess portions having a spherical concave-convex shape, so that the primary surface of the piezoelectric ceramic base is formed.

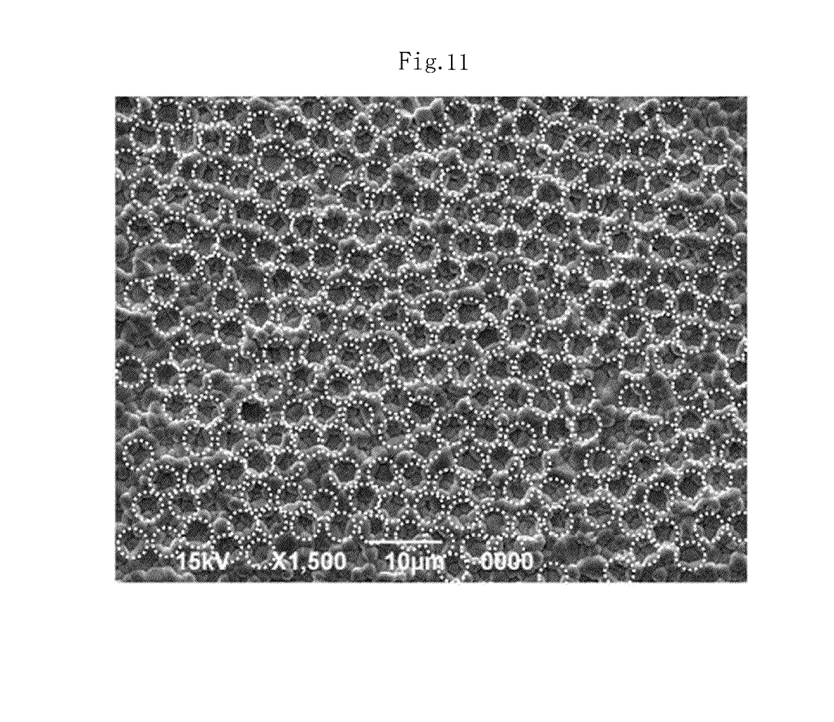

In the SEM image of Sample No. 4 shown in FIG. 11, an area corresponding to the recess portion is shown by a dotted line.

As apparent from FIG. 11, in this example, the recess portion is formed to have an approximately circular shape. In addition, since the contact interface forms the recess portions from crystal particles as described above, a ceramic electronic component can be obtained which has good adhesion between the piezoelectric ceramic base and the external electrode and which can secure desired good mechanical strength.

### EXAMPLE 2

Ceramic green sheets were formed by a method and a procedure similar to those of Example 1.

Next, an internal electrode-forming paste containing Ag—Pd as a primary component was prepared and was applied on a part of a ceramic green sheet to form a ceramic green sheet on which a conductive film was formed.

In addition, ceramic green sheets on each of which the conductive film was formed were laminated so that a piezoelectric ceramic base after firing had a thickness of approximately 150 μm, and a ceramic green sheet on which no conductive film was provided was placed on the top of the ceramic green sheets laminated to each other, so that a multilayer ceramic green sheet was obtained.

Subsequently, after a ceramic molded body was formed by a method and a procedure similar to those of Example 1, firing was performed, so that a piezoelectric ceramic base having recess portions in the primary surfaces was obtained.

Next, after Ag was deposited on both primary surfaces and a side surface of the piezoelectric ceramic base to form external electrodes, a polarization treatment was performed by applying a direct-current voltage between the both primary surfaces, so that test elements of Sample Nos. 21 to 39 were obtained. In this example, Sample Nos. 21 to 37 represent the test elements of the present invention, Sample No. 38 represents a standard test element, and Sample No. 39 represents a sand blast test element.

Next, by using 10 test elements of each of Sample Nos. 21 to 39, the average depth T of the recess portions, the occupation rate of the recess portions, the generation of structural defects, the adhesion strength, and the flexural strength were measured by a method and a procedure similar to those of Example 1.

Table 2 shows the average depth T of the recess portions, the occupation rate (average value) of the recess portions, the presence of the structural defects, the adhesion strength (average value), the average value of the flexural strengths, and the standard deviation σ thereof of, the test elements of each of Sample Nos. 21 to 39.

TABLE 2

| | | | | | Flexural Strength | |
|---|---|---|---|---|---|---|
| | Average Depth | Occupation | Generation | Adhesion | Average | Standard |
| Sample | T of Recess | Rate of Recess | of Structural | Strength | Value | Deviation |
| No. | Portions (μm) | Portions (%) | Defects | (MPa) | (MPa) | σ (—) |
| 21 | 1 | 72 | ∘ | 2.09 | 119 | 5 |
| 22 | 2 | 72 | ∘ | 2.44 | 120 | 5 |
| 23 | 3 | 72 | ∘ | 2.91 | 120 | 7 |
| 24 | 4 | 72 | ∘ | 3.16 | 122 | 4 |
| 25 | 5 | 72 | ∘ | 3.54 | 118 | 4 |
| 26 | 6 | 72 | ∘ | 3.59 | 120 | 5 |
| 27 | 7 | 72 | ∘ | 3.67 | 121 | 6 |
| 28 | 8 | 72 | ∘ | 3.52 | 120 | 4 |
| 29 | 9 | 72 | ∘ | 3.57 | 119 | 7 |
| 30 | 10 | 72 | ∘ | 3.65 | 121 | 8 |
| 31*²⁾ | 15 | 72 | ∘ | 3.73 | 115 | 9 |
| 32*²⁾ | 20 | 72 | ∘ | 3.75 | 112 | 10 |
| 33*³⁾ | 5 | 48 | ∘ | 2.25 | 121 | 7 |
| 34*³⁾ | 5 | 55 | ∘ | 2.51 | 118 | 6 |
| 35*³⁾ | 5 | 62 | ∘ | 2.77 | 122 | 7 |
| 36 | 5 | 67 | ∘ | 3.45 | 120 | 8 |
| 37 | 5 | 70 | ∘ | 3.61 | 121 | 7 |

| | | | | | |
|---|---|---|---|---|---|
| 38*¹⁾ | Standard Element | ∘ | 1.04 | 120 | 6 |
| 39*¹⁾ | Sand Blast Element | x | 3.94 | 91 | 16 |

*¹⁾indicates out of scope of a preferred embodiment of the present invention.
*²⁾indicates out of scope of a preferred embodiment of the present invention.
*³⁾indicates out of scope of a preferred embodiment of the present invention.

In the test element of Sample No. 38, since the contact interface between the piezoelectric ceramic base and the external electrode was flat, and the structural portions, such as the recess portions or the protruding portions, formed from crystal particles were not present, as in the case of Sample No. 18, the adhesion strength was decreased to 1.04 MPa.

In the test element of Sample No. 39, since the primary surface of the piezoelectric ceramic base was roughened by a sand blast treatment, as in the case of Sample No. 19, the adhesion strength was increased to 3.94 MPa as compared to that of the standard element (Sample No. 38). However, on the other hand, since the mechanical strength of the piezoelectric ceramic base itself was decreased by the above roughening, the generation of structural defects, such as cracks and fractures, was observed. In addition, since the flexural strength was decreased to 91 MPa, and the variation thereof was also increased so that the standard deviation σ was 16, the reliability was also degraded.

Even if the internal electrode was embedded in the piezoelectric ceramic base as described above, it was found that as in the case of Example 1, when the structural portions, such as the recess portions or the protruding portions, formed from crystal particles were not present on the primary surface of the piezoelectric ceramic base, and when the primary surface thereof was simply roughened by sand blasting or the like, the structure defects were generated, the mechanical characteristics were degraded, and the reliability was also degraded.

On the other hand, in the test elements of Sample Nos. 21 to 37, it was found that since the recess portions formed from crystal particles were present in the primary surface of the piezoelectric ceramic base at least in contact with the external electrode, the adhesion strength was 2.09 to 3.75 MPa, and the adhesion was improved as compared to that of the standard element (Sample No. 38). In addition, it was also found that a highly reliable ceramic electronic component could be obtained in which the flexural strength had an average value of 112 to 122 MPa and a standard deviation σ of 4 to 10, the structural defects were not generated unlike the case of the sand blast element (Sample No. 39), and good mechanical characteristics could be secured.

However, in the test elements of Sample Nos. 31 and 32, it was found that since the average depth T of the recess portions was 15 to 20 μm, which was more than 10 μm, the flexural strength was slightly decreased to 112 to 115 MPa, and the variation thereof tended to slightly increase so that the standard deviation σ was 9 to 10.

In addition, in the test elements of Sample Nos. 33 to 35, it was found that since the occupation rate of the recess portions was 48% to 62%, which was less than 65%, the adhesion strength was decreased to 2.25 to 2.77 MPa, and the adhesion was slightly degraded.

That is, even if the internal electrode is embedded in the piezoelectric ceramic base, when the primary surface of the piezoelectric ceramic base in contact with the external electrode forms the recess portions from crystal particles, as in the case of Example 1, the adhesion is significantly improved as compared to that of the standard element (Sample No. 38), good mechanical characteristics can be secured unlike the case of the sand blast element (Sample No. 39), and the reliability can be controlled in the acceptable range. In addition, in order to obtain more preferable adhesion and mechanical characteristics and to secure more preferable reliability by suppressing the variation between products, it was found that as in the case of Example 1, the average depth T and the occupation rate of the recess portions were preferably 1 to 10 μm and 65% or more, respectively.

### EXAMPLE 3

By a method and a procedure similar to those of Example 1, test elements of Sample Nos. 41 to 57 were formed.

By using 10 test elements of each of Sample Nos. 41 to 57, the average height H of protruding portions and the occupation rate thereof at the contact interface between the piezoelectric ceramic base and the electrode were obtained by processing an image photographed by a laser microscope.

In addition, by using 10 test elements of each of Sample Nos. 41 to 57, the generation of structural defects, the adhesion strength, and the flexural strength were measured by a method and a procedure similar to those of Example 1.

Table 3 shows the average height H of the protruding portions, the occupation rate (average value) of the protruding portions, the presence of the structural defects, the adhesion strength (average value), the average value of the flexural strengths, and the standard deviation σ thereof, of the test elements of each of Sample Nos. 41 to 57.

TABLE 3

| | | | | | Flexural Strength | |
|---|---|---|---|---|---|---|
| | Average Height | Occupation | Generation | Adhesion | Average | Standard |
| Sample | H of Protruding | Rate of Protruding | of Structural | Strength | Value | Deviation |
| No. | Portions (μm) | Portions (%) | Defects | (MPa) | (MPa) | σ (—) |
| 41 | 0.5 | 30 | ∘ | 2.20 | 105 | 3 |
| 42 | 2 | 30 | ∘ | 2.31 | 103 | 3 |
| 43 | 3 | 30 | ∘ | 2.69 | 106 | 5 |
| 44 | 4 | 30 | ∘ | 2.89 | 107 | 4 |
| 45 | 5 | 30 | ∘ | 3.30 | 103 | 6 |
| 46 | 6 | 30 | ∘ | 3.43 | 105 | 4 |
| 47 | 7 | 30 | ∘ | 3.51 | 102 | 4 |
| 48 | 8 | 30 | ∘ | 3.58 | 104 | 5 |
| 49 | 9 | 30 | ∘ | 3.60 | 105 | 6 |
| 50 | 10 | 30 | ∘ | 3.62 | 104 | 6 |
| 51*⁴⁾ | 15 | 30 | ∘ | 3.68 | 105 | 9 |
| 52*⁴⁾ | 20 | 30 | ∘ | 3.69 | 103 | 10 |
| 53*⁵⁾ | 3 | 5 | ∘ | 2.19 | 107 | 4 |
| 54*⁵⁾ | 3 | 10 | ∘ | 2.26 | 104 | 4 |
| 55*⁵⁾ | 3 | 16 | ∘ | 2.33 | 105 | 5 |
| 56 | 3 | 21 | ∘ | 2.54 | 105 | 4 |
| 57 | 3 | 25 | ∘ | 2.60 | 103 | 5 |

*⁴⁾indicates out of scope of a preferred embodiment of the present invention.
*⁵⁾indicates out of scope of a preferred embodiment of the present invention.

As apparent from Table 3, in the test elements of Sample Nos. 41 to 57, it was found that since the primary surface of the piezoelectric ceramic base had the protruding portions formed from crystal particles, the adhesion strength was 2.19 to 3.69 MPa, and the adhesion was significantly improved as compared to that of the standard element (Table 1, Sample No. 18). In addition, it was also found that a highly reliable ceramic electronic component could be obtained in which the flexural strength had an average value of 102 to 107 MPa and a standard deviation σ of 3 to 10, the structural defects were not generated unlike the case of the sand blast element (Table 1, Sample No. 19), and good mechanical characteristics could be secured.

However, in the test elements of Sample Nos. 51 and 52, it was found that since the average height H of the protruding portions was 15 to 20 μm, which was more than 10 μm, the variation tended to slightly increase so that the standard deviation σ was 9 to 10.

In addition, in the test elements of Sample Nos. 53 to 55, it was found that since the occupation rate of the protruding portions was 5% to 16%, which was less than 20%, the adhesion strength tended to decrease.

Since the primary surface of the piezoelectric ceramic base has the protruding portions formed from crystal particles as described above, the adhesion is significantly improved as compared to that of the standard element (Table 1, Sample No. 18), the mechanical characteristics can be secured without causing the structure defects unlike the case of the sand blast element (Table 1, Sample No. 19), and the reliability can also be controlled in the acceptable range. In addition, in order to obtain more preferable adhesion and mechanical characteristics and to secure more preferable reliability by suppressing the variation between products, it was found that the average height H and the occupation rate of the protruding portions were preferably 0.5 to 10 μm and 20% or more, respectively.

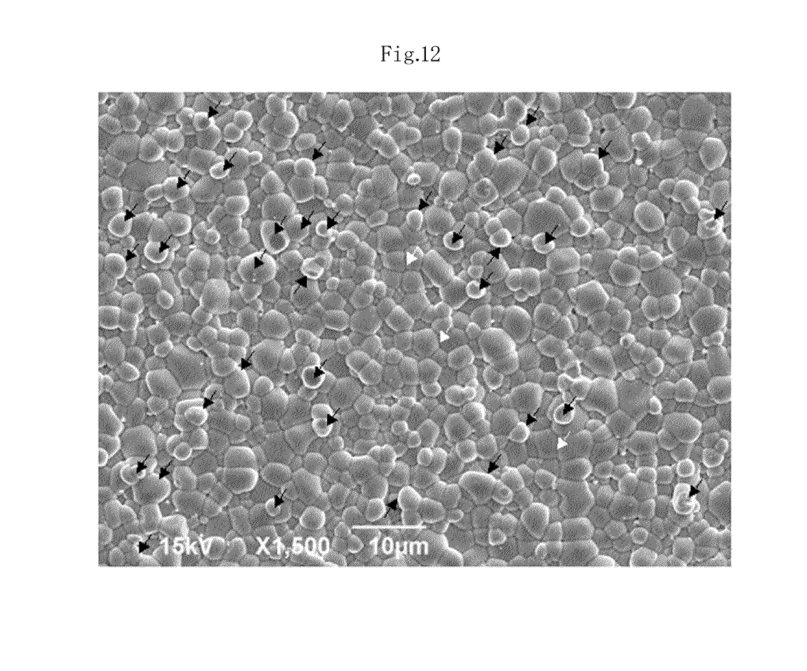

FIG. 12 is a SEM image of the primary surface of the piezoelectric ceramic base of Sample No. 44, the black arrow represents the protruding portion, and the white arrow represents a flat grain boundary portion.

### EXAMPLE 4

By a method and a procedure similar to those of Example 2, test elements of Sample Nos. 61 to 77 were formed.

By using 10 test elements of each of Sample Nos. 61 to 77, the average height H of the protruding portions, the occupation rate thereof, the generation of structural defects, the adhesion strength, and the flexural strength were measured by a method and a procedure similar to those of Example 3.

Table 4 shows the average height H of the protruding portions, the occupation rate (average value) of the protruding portions, the presence of the structural defects, the adhesion strength (average value), the average value of the flexural strengths, and the standard deviation σ thereof, of the test elements of each of Sample Nos. 61 to 77.

TABLE 4

| | | | | | Flexural Strength | |
|---|---|---|---|---|---|---|
| | Average Height | Occupation | Generation | Adhesion | Average | Standard |
| Sample | H of Protruding | Rate of Protruding | of Structural | Strength | Value | Deviation |
| No. | Portions (μm) | Portions (%) | Defects | (MPa) | (MPa) | σ (—) |
| 61 | 0.5 | 30 | ∘ | 2.08 | 120 | 4 |
| 62 | 2 | 30 | ∘ | 2.37 | 119 | 3 |
| 63 | 3 | 30 | ∘ | 2.85 | 117 | 3 |
| 64 | 4 | 30 | ∘ | 3.01 | 122 | 4 |
| 65 | 5 | 30 | ∘ | 3.48 | 120 | 5 |
| 66 | 6 | 30 | ∘ | 3.52 | 116 | 4 |
| 67 | 7 | 30 | ∘ | 3.58 | 116 | 6 |
| 68 | 8 | 30 | ∘ | 3.60 | 115 | 5 |
| 69 | 9 | 30 | ∘ | 3.65 | 118 | 5 |
| 70 | 10 | 30 | ∘ | 3.69 | 117 | 6 |
| 71*⁴⁾ | 15 | 30 | ∘ | 3.71 | 119 | 9 |
| 72*⁴⁾ | 20 | 30 | ∘ | 3.70 | 120 | 9 |
| 73*⁵⁾ | 3 | 5 | ∘ | 2.06 | 122 | 3 |
| 74*⁵⁾ | 3 | 10 | ∘ | 2.30 | 121 | 4 |
| 75*⁵⁾ | 3 | 15 | ∘ | 2.47 | 119 | 4 |
| 76 | 3 | 20 | ∘ | 2.69 | 118 | 4 |
| 77 | 3 | 26 | ∘ | 2.80 | 120 | 5 |

*⁴⁾indicates out of scope of a preferred embodiment of the present invention.
*⁵⁾indicates out of scope of a preferred embodiment of the present invention.

As apparent from Table 4, in the test elements of Sample Nos. 61 to 77, it was found that since the primary surface of the piezoelectric ceramic base at least in contact with the external electrode had the protruding portions formed from crystal particles, the adhesion strength was 2.08 to 3.71 MPa, and the adhesion was significantly improved as compared to that of the standard element (Table 2, Sample No. 38). In addition, it was also found that a highly reliable ceramic electronic component could be obtained in which the flexural strength had an average value of 117 to 122 MPa and a standard deviation σ of 3 to 9, the structural defects were not generated unlike the case of the sand blast element (Table 2, Sample No. 39), and good mechanical characteristics could be secured.

However, in the test elements of Sample Nos. 71 and 72, it was found that since the average height H of the protruding portions was 15 to 20 μm, which was more than 10 μm, the variation tended to slightly increase so that the standard deviation σ was 9.

In addition, in the test elements of Sample Nos. 73 to 75, it was found that since the occupation rate of the protruding portions was 5% to 15%, which was less than 20%, the adhesion strength was decreased to 2.06 to 2.47 MPa, and the adhesion was slightly decreased.

That is, even if the internal electrode is embedded in the piezoelectric ceramic base, when the primary surface of the piezoelectric ceramic base in contact with the external electrode forms the protruding portions from crystal particles, as in the case of Example 2, the adhesion is significantly improved as compared to that of the standard element (Table 2, Sample No. 38), good mechanical characteristics can be secured unlike the case of the sand blast element (Table 2, Sample No. 39), and the reliability can be controlled in the acceptable range. In addition, in order to obtain more preferable adhesion and mechanical characteristics and to secure more preferable reliability by suppressing the variation between products, it was found that as in the case of Example 3, the average height H and the occupation rate of the protruding portions were preferably 0.5 to 10 μm and 20% or more, respectively.

Since the adhesion between the piezoelectric ceramic base and the conductive portion is superior, the generation of structural defects can be avoided, desired good mechanical characteristics can be obtained, and a high reliability can be secured.

### REFERENCE SIGNS LIST

1 piezoelectric ceramic base (ceramic base)

2a, 2b electrode (conductive portion)

3a primary surface

4 spherical concave-convex portion

7a upper die (molding die)

7b lower die (molding die)

11 piezoelectric ceramic base

12 internal electrode

14 external electrode (conductive portion)

16a, 16b primary surface

20 recess portion

31 piezoelectric ceramic base (ceramic base)

31a primary surface

32 electrode (conductive portion)

33 protruding portion

1. A ceramic electronic component comprising:
a ceramic base; and
a conductive portion on at least a part of at least one primary surface of the ceramic base,
wherein in the ceramic base, at least a part of a contact interface in contact with the conductive portion has structural portions formed from crystal particles.

2. The ceramic electronic component according to claim 1, wherein the structural portions include recess portions surrounded by the crystal particles.

3. The ceramic electronic component according to claim 2, wherein the recess portions each have an approximately circular shape when viewed in a plan view.

4. The ceramic electronic component according to claim 2, wherein in the ceramic base, at least a part of the contact interface has a spherical concave-convex shape which form the recess portions.

5. The ceramic electronic component according to claim 1, wherein the recess portions have an average depth of 1 to 10 μm.

6. The ceramic electronic component according to claim 2, wherein an occupation rate of the recess portions at the contact interface is 65% or more of an area ratio.

7. The ceramic electronic component according to claim 2, wherein the recess portions have approximately the same size when viewed in a plan view.

8. The ceramic electronic component according to claim 1, wherein the structural portions include crystal particles that form protruding portions.

9. The ceramic electronic component according to claim 8, wherein the protruding portions have an average height of 0.5 to 10 μm.

10. The ceramic electronic component according to claim 8, wherein an occupation rate of the protruding portions at the contact interface is 20% or more of an area ratio.

11. The ceramic electronic component according to claim 8, wherein the protruding portions are formed to have approximately the same size when viewed in a plan view.

12. The ceramic electronic component according to claim 1, wherein the conductive portion is an internal electrode embedded in the ceramic base.

13. A method for manufacturing a ceramic electronic component, the method comprising:
forming a ceramic green sheet by mold processing of a ceramic raw material;
preparing a molding die having a press surface which at least partially has convex shapes, and pressing at least one primary surface of the ceramic green sheet on the press surface of the molding die to form a ceramic molded body in at least a part of which concave shapes are formed;
firing the ceramic molded body to form a ceramic base in which recess portions surrounded by crystal particles are formed in at least a part of the primary surface; and
forming an electrode on the primary surface of the ceramic base.

14. The method for manufacturing a ceramic electronic component according to claim 13, wherein the recess portions have an average depth of 1 to 10 μm.

15. The method for manufacturing a ceramic electronic component according to claim 13, wherein an occupation rate of the recess portions at a contact interface with the electrode is 65% or more of an area ratio.

16. The method for manufacturing a ceramic electronic component according to claim 13, wherein the recess portions have approximately the same size when viewed in a plan view.

17. A method for manufacturing a ceramic electronic component, the method comprising:
forming a ceramic green sheet by mold processing of a ceramic raw material;
preparing a molding die having a press surface which at least partially has convex shapes, and pressing at least one primary surface of the ceramic green sheet on the press surface of the molding die to form a ceramic molded body in at least a part of which concave shapes are formed;
firing the ceramic molded body to form a ceramic base in which protruding portions are formed on at least a part of the primary surface; and
forming an electrode on the primary surface of the ceramic base.

18. The method for manufacturing a ceramic electronic component according to claim 17, wherein crystal particles form the protruding portions.

19. The method for manufacturing a ceramic electronic component according to claim 17, wherein the protruding portions have an average height of 0.5 to 10 μm.

20. The method for manufacturing a ceramic electronic component according to claim 17, wherein an occupation rate of the protruding portions at a contact interface with the electrode is 20% or more of an area ratio.
